(19) United States
(12) Patent Application Publication
(10) Pub. No.: US 2023/0311145 A1
(43) Pub. Date: Oct. 5, 2023

(54) RAW MATERIAL SUPPLY DEVICE AND RAW MATERIAL SUPPLY METHOD

(71) Applicant: Tokyo Electron Limited, Minato-ku, Tokyo (JP)

(72) Inventor: Eiichi KOMORI, Nirasaki City, Yamanashi (JP)

(21) Appl. No.: 18/043,757

(22) PCT Filed: Sep. 1, 2021
(86) PCT No.: PCT/JP2021/032066

§ 371 Date: Mar. 2, 2023

(30) Foreign Application Priority Data
Sep. 14, 2020 (JP) 2020-154136

(51) Int. Cl. B05B 12/02; B05B 9/04

(52) U.S. Cl. CPC B05B 12/02; B05B 9/04

(57) ABSTRACT

A raw material supply device includes: a container configured to store a solution in which a solid raw material is dissolved in a solvent or a dispersion in which the solid raw material is dispersed in a dispersion medium; an injector configured to spray the solution or the dispersion to inject the solution or the dispersion into the container; and a controller configured to control a spray condition so as to change a spray direction of the solution or the dispersion sprayed from the injector over time.

### TECHNICAL FIELD

The present disclosure relates to a raw material supply device and a raw material supply method.

### BACKGROUND

A technique of dissolving a solid raw material in a solvent to spray it into a processing chamber, then heating the inside of the processing chamber to remove the solvent and leave the solid raw material, and subsequently heating the inside of the processing chamber to sublimate the solid raw material, thereby generating a corresponding gas, has been known (e.g., see Patent Document 1).

### PRIOR ART DOCUMENTS

### Patent Documents

Patent Document 1: Japanese Patent Laid-open Publication No. 2004-115831

The present disclosure provides a technique capable of increasing the sublimation rate of a solid raw material.

### SUMMARY

According to an aspect of the present disclosure, there is provided a raw material supply device including a container configured to store a solution in which a solid raw material is dissolved in a solvent or a dispersion in which the solid raw material is dispersed in a dispersion medium, an injector configured to spray the solution or the dispersion to inject the solution or the dispersion into the container, and a controller configured to control a spray condition so as to temporally change a spray direction of the solution or the dispersion sprayed from the injector.

According to the present disclosure, it is possible to increase the sublimation rate of a solid raw material.

### BRIEF DESCRIPTION OF DRAWINGS

FIG. 1 is a diagram illustrating an example of a raw material supply system according to an embodiment.

FIG. 2 is a diagram (1) illustrating an operation of the raw material supply system of FIG. 1.

FIG. 3 is a diagram (2) illustrating the operation of the raw material supply system of FIG. 1.

FIG. 4 is a diagram (1) illustrating a spray direction.

FIG. 5 is a diagram (2) illustrating the spray direction.

FIG. 6 is a diagram illustrating a raw material supply device of a modification.

### DETAILED DESCRIPTION

Hereinafter, non-limiting exemplary embodiments of the present disclosure will be described with reference to the accompanying drawings. In all the accompanying drawings, the same or corresponding members or components will be denoted by the same or corresponding reference numerals, and redundant descriptions thereof will be omitted.

### (Raw Material Supply System)

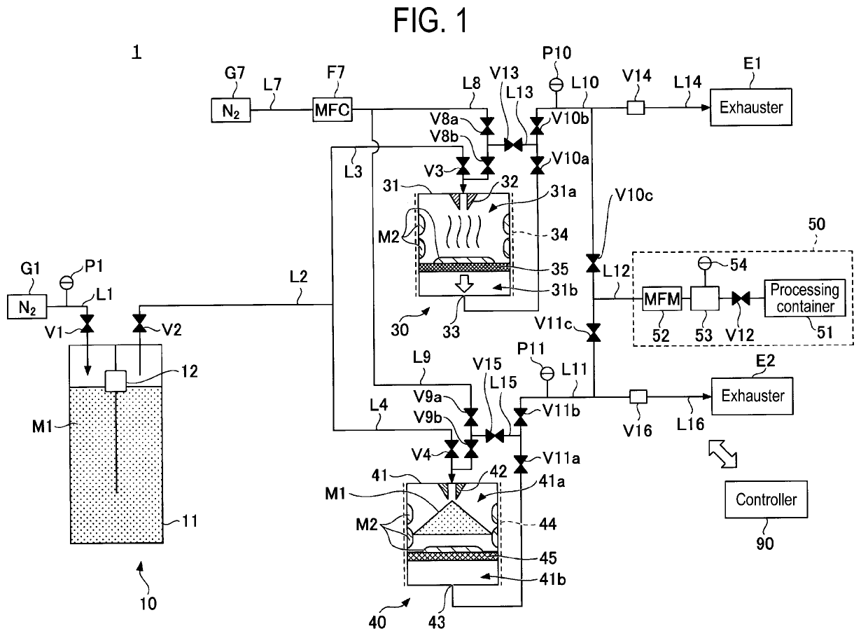

A raw material supply system of an embodiment will be described with reference to FIG. 1. FIG. 1 is a diagram illustrating an example of a raw material supply system according to an embodiment.

The raw material supply system 1 is a system that sublimates a second solid raw material, which is formed by removing a solvent from a solution in which a first solid raw material is dissolved in the solvent (hereinafter, simply referred to as “solution”), to generate a reactive gas, and forms a film in a processing device using the generated reactive gas.

The first solid raw material is not particularly limited, but may be, for example, an organometallic complex containing a metal element such as strontium (Sr), molybdenum (Mo), ruthenium (Ru), zirconium (Zr), hafnium (Hf), tungsten (W), or aluminum (Al), or a chloride containing a metal element such as tungsten (W) or aluminum (Al). The solvent only needs to be capable of dissolving the first solid raw material to form the solution, and may be, for example, hexane.

The raw material supply system 1 includes a raw material supply source 10, raw material supply devices 30 and 40, a processing device 50, and a controller 90.

The raw material supply source 10 supplies a solution M1 to the raw material supply devices 30 and 40. The raw material supply source 10 is located, for example, in a sub-fab. In the present embodiment, the raw material supply source 10 includes a tank 11 and a float sensor 12. The tank 11 is filled with the solution M1. The float sensor 12 detects the amount of the solution M1 filling the tank 11.

One end of a pipe L1 is inserted into the raw material supply source 10 from above the tank 11. The other end of the pipe L1 is connected to a carrier gas supply source G1, and a carrier gas is supplied from the supply source G1 into the tank 11 through the pipe L1. The carrier gas may be, for example, an inert gas such as nitrogen (N₂) or argon (Ar). A valve V1 is interposed in the pipe L1. When the valve V1 is opened, the carrier gas is supplied from the supply source G1 to the raw material supply source 10. When the valve V1 is closed, the supply of the carrier gas from the supply source G1 to the raw material supply source 10 is cut off. The pipe L1 is provided with a pressure sensor P1 that detects the pressure inside the pipe L1. A detected value of the pressure sensor P1 is transmitted to the controller 90. Further, a flow rate controller (not illustrated) that controls the flow rate of the carrier gas flowing through the pipe L1, an additional valve, and the like may be interposed in the pipe L1.

The raw material supply source 10 is connected to the raw material supply device 30 through pipes L2 and L3, and supplies the solution M1 to the raw material supply device 30 through the pipes L2 and L3. Valves V2 and V3 are interposed in the pipes L2 and L3, respectively. When the valves V2 and V3 are opened, the solution M1 is supplied from the raw material supply source 10 to the raw material supply device 30, and when the valves V2 and V3 are closed, the supply of the solution M1 from the raw material supply source 10 to the raw material supply device 30 is cut off. Further, a flow rate controller (not illustrated) that controls the flow rate of the solution M1 flowing through the pipe L3, an additional valve, and the like may be interposed in the pipe L3.

Further, the raw material supply source 10 is connected to the raw material supply device 40 through the pipe L2 and a pipe L4, and supplies the solution M1 to the raw material supply device 40 through the pipes L2 and L4. A valve V4 is interposed in the pipe L4. When the valves V2 and V4 are opened, the solution M1 is supplied from the raw material supply source 10 to the raw material supply device 40. When the valves V2 and V4 are closed, the supply of the solution M1 from the raw material supply source 10 to the raw material supply device 40 is cut off. Further, a flow rate controller (not illustrated) that controls the flow rate of the solution M1 flowing through the pipe L4, an additional valve, and the like may be interposed in the pipe L4.

The raw material supply device 30 stores the solution M1 transported from the raw material supply source 10. In the present embodiment, the raw material supply device 30 includes a container 31, an injector 32, an evacuation port 33, a heater 34, and a filter 35.

The container 31 stores the solution M1 transported from the raw material supply source 10.

The injector 32 sprays the solution M1, supplied from the raw material supply source 10 through the pipes L2 and L3, to inject it into the container 31. The injector 32 vaporizes the solvent before the solution M1 reaches the filter 35 by spraying the solution M1. The injector 32 may be, for example, a spray nozzle. For example, the spray nozzle may be fixed to the ceiling of the container 31, or may be installed on the ceiling of the container 31 such that the orientation of the nozzle central axis may be changed.

The evacuation port 33 is provided in the bottom of the container 31, and evacuates the inside of the container 31. The processing device 50 is connected to the evacuation port 33 through pipes L10 and L12. Further, an exhauster E1 is connected to the evacuation port 33 through the pipe L10 and a pipe L14.

The heater 34 heats a solid raw material, which is formed by removing the solvent from the solution M1 (hereinafter, referred to as “second solid raw material M2”), thereby sublimating the second solid raw material M2 to generate a reactive gas. The heater 34 may be, for example, a heater arranged to cover the outer periphery of the container 31. The heater 34 is configured to be able to heat the inside of the container 31 up to a temperature at which the second solid raw material M2 may be sublimated to generate a reactive gas.

The filter 35 is provided substantially horizontally in the container 31, and divides the inside of the container 31 into a first region 31a and a second region 31b. The injector 32 is provided in the first region 31a. The second region 31b is a region located below the first region 31a. The evacuation port 33 is provided in the second region 31b. The filter 35 only needs to be formed of a material that permeates the reactive gas and traps impurities such as the second solid raw material M2 and particles, and is formed of, for example, a porous material.

The porous material may be, for example, a porous metal material such as a sintered body of stainless steel, or a porous ceramic material.

One end of a pipe L8 is connected to the downstream side of the valve V3 in the pipe L3. The other end of the pipe L8 is connected to a carrier gas supply source G7 through a pipe L7, and a carrier gas is supplied from the supply source G7 into the container 31 through the pipes L7, L8, and L3. The carrier gas may be, for example, an inert gas such as N₂ or Ar. Valves V8a and V8b are interposed in the pipe L8 in order from the supply source G7 side. When the valves V8a and V8b are opened, the carrier gas is supplied from the supply source G7 to the raw material supply device 30. When valves V8a and V8b are closed, the supply of the carrier gas from the supply source G7 to the raw material supply device 30 is cut off. A flow rate controller F7 that controls the flow rate of the carrier gas flowing through the pipe L7 is interposed in the pipe L7. In the present embodiment, the flow rate controller F7 is a mass flow controller (MFC).

The raw material supply device 30 is connected to the processing device 50 through the pipes L10 and L12, and supplies the reactive gas to the processing device 50 through the pipes L10 and L12. Valves V10a to V10c are interposed in the pipe L10 in order from the raw material supply device 30 side. When the valves V10a to V10c are opened, the reactive gas is supplied from the raw material supply device 30 to the processing device 50. When the valves V10a to V10c are closed, the supply of the reactive gas from the raw material supply device 30 to the processing device 50 is cut off. The pipe L10 is provided with a pressure sensor P10 that detects the pressure inside the pipe L10. A detected value of the pressure sensor P10 is transmitted to the controller 90.

One end of a pipe L13 is connected between the valve V10a and the valve V10b in the pipe L10. The other end of the pipe L13 is connected to the pipe L8 between the valve V8a and the valve V8b. The pipe L13 functions as a bypass pipe that interconnects the pipe L8 and the pipe L10 without passing through the raw material supply device 30. A valve V13 is interposed in the pipe L13. When the valve V13 is opened, the pipe L8 and the pipe L10 communicate with each other, and when the valve V13 is closed, communication between the pipe L8 and the pipe L10 is cut off.

One end of the pipe L14 is connected to the pipe L10 between the valve V10b and the valve V10c. The other end of the pipe L14 is connected to the exhauster E1 such as a vacuum pump, for example. A pressure control valve V14 is interposed in the pipe L14. When the pressure control valve V14 is opened while the valves V10a and V10b are open, the inside of the container 31 is evacuated, and the solvent may be removed from the solution M1 stored in the container 31. When the pressure control valve V14 is closed, the removal of the solvent from the solution M1 stored in the container 31 may stop. Further, the pressure inside a container 41 may be controlled by adjusting the opening degree of the pressure control valve V14.

The raw material supply device 40 stores the solution M1 transported from the raw material supply source 10. The raw material supply device 40 is provided in parallel to the raw material supply device 30. In the present embodiment, the raw material supply device 40 includes the container 41, an injector 42, an evacuation port 43, a heater 44, and a filter 45.

The container 41 stores the solution M1 transported from the raw material supply source 10.

The injector 42 sprays the solution M1, supplied from the raw material supply source 10 through the pipes L2 and L4, to inject it into the container 41. The injector 42 vaporizes the solvent before the solution M1 reaches the filter 45 by spraying the solution M1. The injector 42 may be, for example, a spray nozzle. For example, the spray nozzle may be fixed to the ceiling of the container 41, or may be installed on the ceiling of the container 41 such that the orientation of the nozzle central axis may be changed.

The evacuation port 43 is provided in the bottom of the container 41, and evacuates the inside of the container 41. The processing device 50 is connected to the evacuation port 43 through a pipe L11 and the pipe L12. Further, an exhauster E2 is connected to the evacuation port 43 through pipes L11 and L16.

The heater 44 heats the second solid raw material M2, formed by removing the solvent from the solution M1, thereby sublimating the second solid raw material M2 to generate a reactive gas. The heater 44 may be, for example, a heater arranged to cover the outer periphery of the container 41. The heater 44 is configured to be able to heat the inside of the container 41 up to a temperature at which the second solid raw material M2 may be sublimated to generate a reactive gas.

The filter 45 is provided substantially horizontally in the container 41, and divides the inside of the container 41 into a first region 41a and a second region 41b. The injector 42 is provided in the first region 41a. The second region 41b is a region located below the first region 41a. The evacuation port 43 is provided in the second region 41b. The filter 45 is formed of the same material as the filter 35, for example.

One end of a pipe L9 is connected to the downstream side of the valve V4 in the pipe L4. The other end of the pipe L9 is connected to the carrier gas supply source G7 through a pipe L7, and the carrier gas is supplied from the supply source G7 into the container 41 through the pipes L7, L9, and L4. The carrier gas may be, for example, an inert gas such as N₂ or Ar. Valves V9a and V9b are interposed in the pipe L9 in order from the supply source G7 side. When the valves V9a and V9b are opened, the carrier gas is supplied from the supply source G7 to the raw material supply device 40. When the valves V9a and V9b are closed, the supply of the carrier gas from the supply source G7 to the raw material supply device 40 is cut off.

The raw material supply device 40 is connected to the processing device 50 through the pipes L11 and L12, and supplies the reactive gas to the processing device 50 through the pipes L11 and L12. Valves V11a to V11c are interposed in the pipe L11 in order from the raw material supply device 40 side. When the valves V11a to V11c are opened, the reactive gas is supplied from the raw material supply device 40 to the processing device 50. When the valves V11a to V11c are closed, the supply of the reactive gas from the raw material supply device 40 to the processing device 50 is cut off. The pipe L11 is provided with a pressure sensor P11 that detects the pressure inside the pipe L11. A detected value of the pressure sensor P11 is transmitted to the controller 90.

One end of a pipe L15 is connected to the pipe L11 between the valve V11a and the valve V11b. The other end of the pipe L15 is connected to the pipe L9 between the valve V9a and the valve V9b. The pipe L15 functions as a bypass pipe that interconnects the pipe L9 and the pipe L11 without passing through the raw material supply device 40. A valve V15 is interposed in the pipe L15. When the valve V15 is opened, the pipe L9 and the pipe L11 communicate with each other, and when the valve V15 is closed, communication between the pipe L9 and the pipe L11 is cut off.

One end of a pipe L16 is connected to the pipe L11 between the valve V11b and the valve V11c. The other end of the pipe L16 is connected to the exhauster E2 such as a vacuum pump, for example. A pressure control valve V16 is interposed in the pipe L16. When the pressure control valve V16 is opened while the valves V11a and V11b are open, the inside of the container 41 is evacuated, and the solvent may be removed from the solution M1 stored in the container 41. When the pressure control valve V16 is closed, the removal of the solvent from the solution M1 stored in the container 41 may stop. Further, the pressure inside the container 41 may be controlled by adjusting the opening degree of the pressure control valve V16.

The processing device 50 is connected to the raw material supply device 30 through the pipes L10 and L12, and the reactive gas, which is generated by heating the second solid raw material M2 in the raw material supply device 30 to sublimate it, is supplied to the processing device 50. Further, the processing device 50 is connected to the raw material supply device 40 through the pipes L11 and L12, and the reactive gas, which is generated by heating the second solid raw material M2 in the raw material supply device 40 to sublimate it, is supplied to the processing device 50.

The processing device 50 performs various types of processing such as film formation on a substrate such as a semiconductor wafer using the reactive gas supplied from the raw material supply devices 30 and 40. In the present embodiment, the processing device 50 includes a processing container 51, a flow meter 52, a storage tank 53, a pressure sensor 54, and a valve V12. The processing container 51 accommodates one or a plurality of substrates. In the present embodiment, the flow meter 52 is a mass flow meter (MFM). The flow meter 52 is interposed in the pipe L12 and measures the flow rate of the reactive gas flowing through the pipe L12. The storage tank 53 temporarily stores the reactive gas. By providing the storage tank 53, a large flow rate of reactive gas may be supplied into the processing container 51 within a short time. The storage tank 53 is also called a buffer tank or a fill tank. The pressure sensor 54 detects the pressure inside the storage tank 53. The pressure sensor 54 is, for example, a capacitance manometer. The valve V12 is interposed in the pipe L12. When the valve V12 is opened, the reactive gas is supplied from the raw material supply devices 30 and 40 to the processing container 51, and when the valve V12 is closed, the supply of the reactive gas from the raw material supply devices 30 and 40 to the processing container 51 is cut off

The controller 90 is an example of a controller and controls each part of the raw material supply system 1. For example, the controller 90 controls operations of the raw material supply source 10, the raw material supply devices 30 and 40, the processing device 50, and the like. Further, the controller 90 controls the opening and closing of various valves. The controller 90 may be, for example, a computer.

The controller 90 controls the spray condition so as to temporally change the spray direction of the solution M1 sprayed from the injectors 32 and 42. For example, the controller 90 temporally changes the spray direction of the solution M1 sprayed from the injectors 32 and 42 by continuously changing the spray condition. Further, for example, the controller 90 changes the spray condition stepwise, thereby temporally changing the spray direction of the solution M1 sprayed from the injectors 32 and 42.

The spray condition includes, for example, the spray pressure, the pressure inside the containers 31 and 41, the temperature inside the containers 31 and 41, and the orientation of the nozzle central axis. For example, the controller 90 controls the spray pressure by adjusting the flow rate of the carrier gas supplied from the supply source G1 into the tank 11 based on the detected value of the pressure sensor P1. Further, for example, the controller 90 controls the pressure inside the container 31 by adjusting the opening degree of the pressure control valve V14 based on the detected value of the pressure sensor P10. Further, for example, the controller 90 controls the pressure inside the container 41 by adjusting the opening degree of the pressure control valve V16 based on the detected value of the pressure sensor P11. Further, for example, the controller 90 controls the temperature inside the container 31 by adjusting the set temperature of the heater 34. Further, for example, the controller 90 controls the temperature inside the container 41 by adjusting the set temperature of the heater 44. Further, for example, the controller 90 controls the orientation of the nozzle central axis of the spray nozzle.

The spray direction is a direction in which the amount of spray per unit time and per unit solid angle is maximized. The spray direction includes, for example, a spray pattern and a spray angle. The spray pattern is a cross-sectional shape when the solution sprayed from the spray nozzle spreads. The spray angle is the angle at which the solution sprayed from the spray nozzle spreads.

### (Operation of Raw Material Supply System)

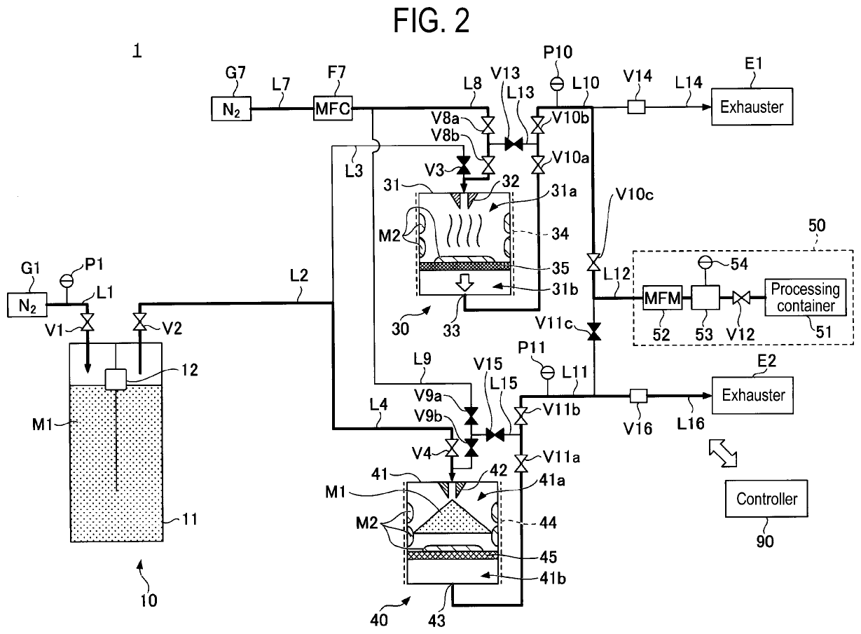

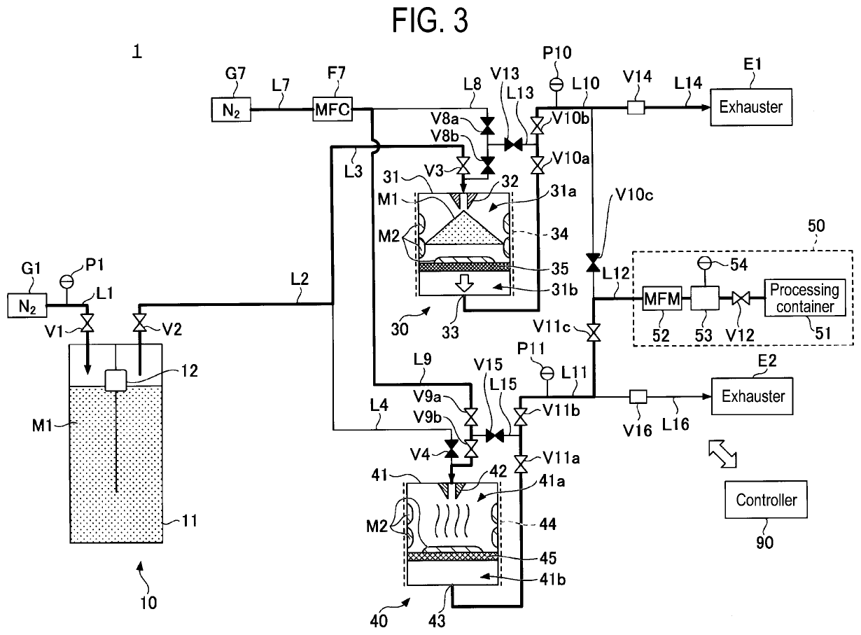

Referring to FIGS. 2 and 3, an example of an operation (raw material supply method) of the raw material supply system 1 will be described. In the raw material supply system 1, the controller 90 controls the opening and closing of various valves, so that one of two raw material supply devices 30 and 40 provided in parallel performs the supply of the reactive gas to the processing device 50, and the other one performs the filling of the solid raw material. Hereinafter, an example of an operation of the raw material supply system 1 will be described in detail.

First, a case where the raw material supply device 30 supplies the reactive gas to the processing device 50 and the raw material supply device 40 fills the solid raw material will be described with reference to FIG. 2. FIG. 2 is a diagram illustrating an operation of the raw material supply system 1 of FIG. 1. In FIG. 2, thick solid lines indicate piping through which the carrier gas, the solution M1, and the reactive gas are flowing, and thin solid lines indicate piping through which the carrier gas, the solution M1, and the reactive gas are not flowing. Further, in FIG. 2, a white symbol indicates the open state of the valve, and a black symbol indicates the closed state of the valve. In addition, it is assumed that in the initial state of the raw material supply system 1, as illustrated in FIG. 1, all of the valves are closed, and the second solid raw material M2 is stored in the raw material supply device 30.

The controller 90 controls the heater 34 of the raw material supply device 30 to heat and sublimate the second solid raw material M2 inside the container 31, thereby generating a reactive gas (sublimation step). Further, the controller 90 opens the valves V8a, V8b, V10a to V10c, and V12. Thereby, the carrier gas is injected from the supply source G7 into the container 31 of the raw material supply device 30 through the pipes L7 and L8, and the reactive gas generated inside the container 31 is supplied to the processing container 51 through the pipes L10 and L12. In the sublimation step, the second solid raw material M2 is deposited over a wide range of the inner sidewall of the container 31 and the filter 35 in a filling/drying step to be described later, so that the second solid raw material M2 has a large specific surface area. Thereby, the sublimation rate of the second solid raw material M2 may be increased.

Further, the controller 90 opens the valves V1, V2, and V4, as illustrated in FIG. 2. Thereby, the carrier gas is supplied from the supply source G1 to the raw material supply source 10, and the solution M1 is transported from the raw material supply source 10 to the raw material supply device 40 through the pipes L2 and L4. The solution M1 transported to the raw material supply device 40 is sprayed into the container 41 from the injector 42. The solution M1 sprayed into the container 41 is deposited as the second solid raw material M2 on the inner sidewall of the container 41 and the filter 45 as the solvent vaporizes. Thereby, the container 41 of the raw material supply device 40 is filled with the second solid raw material M2 (filling/drying step).

In the filling/drying step, the controller 90 controls the spray condition so as to temporally change the spray direction of the solution M1 sprayed from the injector 42.

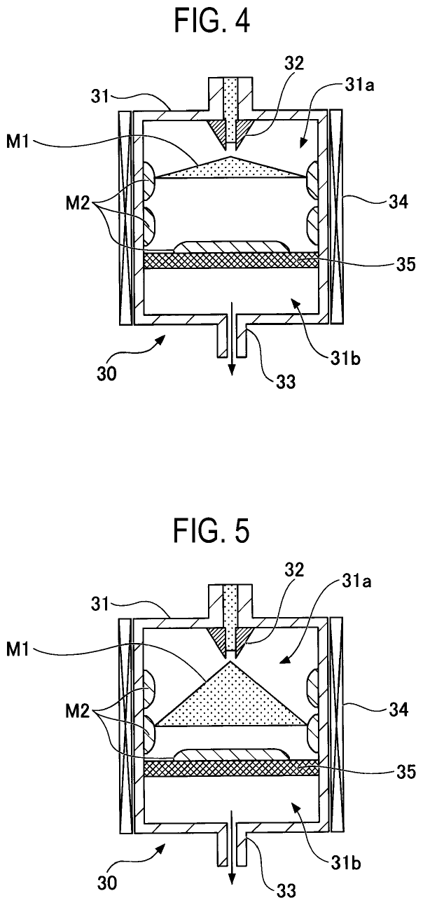

FIGS. 4 and 5 are diagrams illustrating the spray direction. For example, the controller 90 performs a step of spraying the solution M1 under a spray condition (see FIG. 4) in which a large amount of the solution M1 is sprayed onto an upper portion of the inner sidewall of the container 31 and a step of spraying the solution M1 under a spray condition (see FIG. 5) in which a large amount of the solution M1 is sprayed onto a lower portion of the inner sidewall of the container 31. Thereby, the solution M1 is sprayed from the injector 42 over a wide range of the inner sidewall of the container 41 and the filter 45, so that the second solid raw material M2 is deposited over a wide range of the inner sidewall of the container 41 and the filter 45.

Further, the controller 90 opens the valves V11a and V11b and the pressure control valve V16. Thereby, the inside of the container 41 of the raw material supply device 40 is evacuated by the exhauster E2, so that the vaporized solvent is removed by spraying the solution M1 into the container 41.

Next, a case where the raw material supply device 40 supplies the reactive gas to the processing device 50 and the raw material supply device 30 fills the solid raw material will be described with reference to FIG. 3. FIG. 3 is a diagram illustrating an operation of the raw material supply system 1 of FIG. 1. In FIG. 3, thick solid lines indicate piping through which the carrier gas, the solution M1, and the reactive gas are flowing, and thin solid lines indicate piping through which the carrier gas, the solution M1, and the reactive gas are not flowing. Further, in FIG. 3, a white symbol indicates the open state of the valve, and a black symbol indicates the closed state of the valve. In addition, it is assumed that in the initial state of the raw material supply system 1, as illustrated in FIG. 1, all of the valves are closed. Further, as illustrated in FIG. 3, it is assumed that the raw material supply device 40 stores the second solid raw material M2.

The controller 90 controls the heater 44 of the raw material supply device 40 to heat and sublimate the second solid raw material M2 inside the container 41, thereby generating a reactive gas (sublimation step). Further, the controller 90 opens the valves V9a, V9b, V11a to V11c, and V12. Thereby, the carrier gas is injected from the supply source G7 into the container 41 of the raw material supply device 40 through the pipes L7 and L9, and the reactive gas generated inside the container 41 is discharged, together with the carrier gas, into the processing container 51 through the pipes L11 and L12. In the sublimation step, the second solid raw material M2 is deposited over a wide range of the inner sidewall of the container 41 and the filter 45 in a filling/drying step to be described later, so that the second solid raw material M2 has a large specific surface area. Thereby, the sublimation rate of the second solid raw material M2 may be increased.

Further, the controller 90 opens the valves V1, V2, and V3, as illustrated in FIG. 3. Thereby, the carrier gas is supplied from the supply source G1 to the raw material supply source 10, and the solution M1 is transported from the raw material supply source 10 to the raw material supply device 30 through the pipes L2 and L3. The solution M1 transported to the raw material supply device 30 is sprayed into the container 31 from the injector 32. The solution M1 sprayed into the container 31 is deposited as the second solid raw material M2 on the inner sidewall of the container 31 and the filter 35 as the solvent vaporizes. Thereby, the container 31 of the raw material supply device 30 is filled with the second solid raw material M2 (filling/drying step).

In the filling/drying step, the controller 90 controls the spray condition so as to temporally change the spray direction of the solution M1 sprayed from the injector 32. Thereby, the solution M1 is sprayed from the injector 32 over a wide range of the inner sidewall of the container 31 and the filter 35, the second solid raw material M2 is deposited over a wide range of the inner sidewall of the container 31 and the filter 35.

Further, the controller 90 opens the valves V10a and V10b and the pressure control valve V14. Thereby, the inside of the container 31 of the raw material supply device 30 is evacuated by the exhauster E1, so that the vaporized solvent is removed by spraying the solution M1 into the container 31.

As described above, according to the embodiment, the controller 90 controls the opening and closing of the valves, so that one of the two raw material supply devices 30 and 40 performs the supply of the reactive gas to the processing device 50, and the other one performs the filling of the solid raw material. Thereby, it is possible to automatically replenish the raw material to the raw material supply devices 30 and 40, to improve the continuous operation capability of the processing device 50, and to improve the operating rate of the processing device 50.

Further, according to the embodiment, the controller 90 controls the spray condition so as to temporally change the spray direction of the solution M1 sprayed from the injectors 32 and 42. Thereby, the solution M1 is sprayed from the injectors 32 and 42 over a wide range of the inner sidewall of the containers 31 and 41 and the filters 35 and 45, so that the second solid raw material M2 is deposited over a wide range of the inner sidewall of the containers 31 and 41 and the filters 35 and 45. As a result, the specific surface area of the second solid raw material M2 is increased, so that the sublimation rate when sublimating the second solid raw material M2 may be increased.

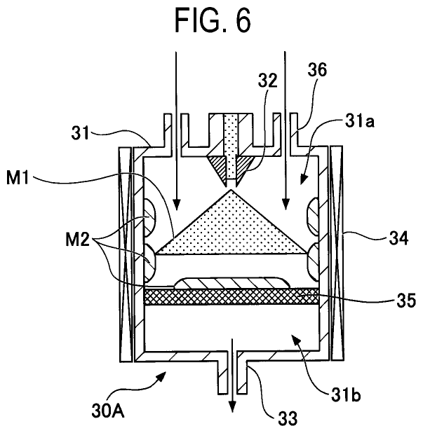

Next, a modification of the raw material supply device 30 will be described. FIG. 6 is a diagram illustrating a raw material supply device of a modification.

The raw material supply device 30A of the modification differs from the raw material supply device 30 in that it further includes a gas outlet 36. In addition, the following description will be focused on differences from the raw material supply device 30 since the others are the same as those of the raw material supply device 30.

The raw material supply device 30A includes the container 31, the injector 32, the evacuation port 33, the heater 34, the filter 35, and the gas outlet 36.

The gas outlet 36 is provided on the ceiling of the container 31. The gas outlet 36 discharges a counter gas toward the solution M1 sprayed into the container 31. Thereby, the spray direction of the solution M1 sprayed into the container 31 is changed by the counter gas. In the present embodiment, the gas outlet 36 is provided around the injector 32. The counter gas may be, for example, the same gas as the carrier gas, for example, an inert gas such as N₂ or Ar.

The controller 90 adjusts conditions such as the flow rate of the counter gas discharged from the gas outlet 36, thereby temporally changing the spray direction of the solution M1 sprayed from the injector 32. Thereby, the solution M1 is sprayed from the injector 32 over a wide range of the inner sidewall of the container 31 and the filter 35, so that the second solid raw material M2 is deposited over a wide range of the inner sidewall of the container 31 and the filter 35. As a result, the specific surface area of the second solid raw material M2 is increased, so that the sublimation rate when sublimating the second solid raw material M2 may be increased.

In addition, in the modification, the raw material supply device 30A has been described as the modification of the raw material supply device 30, but may also be equally applied to a modification of the raw material supply device 40.

The embodiments disclosed herein should be considered to be exemplary and not limitative in all respects. The above embodiments may be omitted, replaced, or modified in various embodiments without departing from the scope of the appended claims and their gist.

In the above embodiment, a case where the raw material supply system 1 has two raw material supply devices 30 and 40 provided in parallel has been described, but the present disclosure is not limited to this. For example, one raw material supply device may be provided, or three or more raw material supply devices may be provided in parallel. However, from the viewpoint of eliminating the downtime associated with the filling of the solution M1, it is preferable that there are two or more raw material supply devices.

In the above embodiment, a system that sublimates the second solid raw material M2, formed by removing the solvent from the solution M1, to generate the reactive gas, and forms a film in the processing device 50 using the generated reactive gas has been described, but the present disclosure is not limited to this. For example, instead of the solution M1, a dispersion such as a slurry in which the first solid raw material is dispersed in a dispersion medium, or a colloidal solution in which the first solid raw material is dispersed in a dispersion medium may be used. For example, when using the colloidal solution, it is possible to fill a precursor with a higher concentration than when using the solution (M1) or the slurry. The dispersion includes a slurry and a colloid as a subordinate concept. The slurry is also called a suspension. The colloid includes a colloidal solution as a subordinate concept. The colloidal solution is also called a sol.

This international application claims priority to Japanese Patent Application No. 2020-154136 filed on Sep. 14, 2020, which is incorporated herein by reference in its entirety.

### EXPLANATION OF REFERENCE NUMERALS

30, 40: raw material supply device, 31, 41: container, 31a, 41a: first region, 31b, 41b: second region, 32, 42: injector, 35, 45: filter, 36: gas outlet, 90: control device, 50: processing device, E1, E2: exhauster

1-16. (canceled)

17. A raw material supply device comprising:
a container configured to store a solution in which a solid raw material is dissolved in a solvent or a dispersion in which the solid raw material is dispersed in a dispersion medium;
an injector configured to spray the solution or the dispersion to inject the solution or the dispersion into the container; and
a controller configured to control a spray condition so as to change a spray direction of the solution or the dispersion sprayed from the injector over time.

18. The raw material supply device of claim 17, wherein the controller continuously changes the spray condition.

19. The raw material supply device of claim 18, wherein the spray condition includes a spray pressure.

20. The raw material supply device of claim 19, wherein the spray condition includes a pressure inside the container.

21. The raw material supply device of claim 20, wherein the spray condition includes a temperature inside the container.

22. The raw material supply device of claim 21, further comprising a gas outlet configured to discharge a gas toward the solution or the dispersion sprayed into the container.

23. The raw material supply device of claim 22, further comprising:
an evacuation port configured to evacuate an inside of the container; and
a filter configured to divide the inside of the container into a first region including the injector and a second region including the evacuation port.

24. The raw material supply device of claim 23, wherein the filter is provided substantially horizontally inside the container.

25. The raw material supply device of claim 24, wherein the filter is formed of a porous material.

26. The raw material supply device of claim 25, wherein the second region is located below the first region.

27. The raw material supply device of claim 26, wherein the injector vaporizes the solvent or the dispersion medium before the solution or the dispersion reaches the filter.

28. The raw material supply device of claim 27, wherein the evacuation port is connected to a processing device.

29. The raw material supply device of claim 28, wherein the evacuation port is connected to an exhauster that evacuates the inside of the container.

30. The raw material supply device of claim 29, wherein the dispersion is a slurry or a colloidal solution.

31. The raw material supply device of claim 17, wherein the controller changes the spray condition stepwise.

32. The raw material supply device of claim 17, wherein the spray condition includes a spray pressure.

33. The raw material supply device of claim 17, wherein the spray condition includes a pressure inside the container.

34. The raw material supply device of claim 17, wherein the spray condition includes a temperature inside the container.

35. The raw material supply device of claim 17, further comprising a gas outlet configured to discharge a gas toward the solution or the dispersion sprayed into the container.

36. A raw material supply method comprising:
spraying a solution in which a solid raw material is dissolved in a solvent or a dispersion in which the solid raw material is dispersed in a dispersion medium into a container, thereby vaporizing and removing the solvent or the dispersion medium from the solution or the dispersion,
wherein, in the spraying, a spray direction of the solution or the dispersion is changed over time.
